(19) United States
(12) Patent Application Publication
(10) Pub. No.: US 2013/0168674 A1
(43) Pub. Date: Jul. 4, 2013

(54) Methods and Systems for Repairing Interior Device Layers in Three-Dimensional Integrated Circuits

(71) Applicant: Rambus Inc., Sunnyvale, CA (US)

(72) Inventors: Paul D. Franzon, New Hill, NC (US); Thomas Vogelsang, Mountain View, CA (US); Frederick A. Ware, Los Altos Hills, CA (US); Wayne Ellis, Saratoga, CA (US)

(73) Assignee: RAMBUS INC., Sunnyvale, CA (US)

(21) Appl. No.: 13/719,724

(22) Filed: Dec. 19, 2012

Related U.S. Application Data
(60) Provisional application No. 61/580,823, filed on Dec. 28, 2011.

(51) Int. Cl. H01L 23/48; H01L 27/10

(52) U.S. Cl. CPC H01L 23/481; H01L 22/34; H01L 27/10
USPC 257/48; 438/17; 257/529

(57) ABSTRACT

A three-dimensional integrated circuit (3D-IC) includes a stack of semiconductor wafers, each of which includes a substrate and a device layer. Programmable components, such as memory arrays or logic circuits, are formed within the device layers. Some of the programmable components are redundant, and can be substituted for defective components by programming passive memory elements in a separate conductive layer provided for this purpose. The separate conductive layer is devoid of active devices, and is therefore relatively reliable and inexpensive.

### TECHNICAL FIELD

The present invention relates to three-dimensional integrated circuits, and in particular to methods and circuits for repairing interior layers of stacked devices.

### BACKGROUND

A three-dimensional integrated circuit (3D-IC) is an IC in which two or more layers of active electronic components are integrated both vertically and horizontally into a single device. One type of 3D-IC is formed by stacking two or more semiconductor wafers. Each wafer includes a two-dimensional array of ICs. These arrays are aligned and the wafers bonded to form rows and columns of IC stacks. The resultant wafer stack is then diced into 3D-ICs.

One or more wafers in a stack can be thinned before bonding, which reduces device thickness, helps dissipate heat, and facilitates the creation of electrical paths through the wafer stack. Electrical connections that extend between layers, called “through-silicon vias” (TSVs), can be formed in the wafers before or after bonding.

3D-ICs tend to experience reduced yields because defects in any of the constituent layers, or that result from the bonding process, can render the entire 3D-IC unfit for use. Yield can be improved by testing the devices on each wafer before bonding. Unfortunately, the additional testing is expensive and time consuming, and these deficits can offset or eliminate the advantages otherwise associated with 3D-ICs.

### BRIEF DESCRIPTION OF THE FIGURES

The present invention is illustrated by way of example, and not by way of limitation, in the figures of the accompanying drawings and in which like reference numerals refer to similar elements and in which:

FIG. 1 depicts a three-dimensional integrated circuit (3D-IC) stack 100 that includes a stack of semiconductor wafers 105 and 110.

FIG. 2 is a block diagram 200 depicting aspects of an embodiment of 3D-IC stack 100 of FIG. 1, with like-identified elements being the same or similar.

FIG. 3 depicts a 3D-IC 300 in accordance with an embodiment that supports different types of post-bonding repairs to memory and other circuit resources.

FIG. 4 depicts a 3D-IC 400 in accordance with an embodiment that supports post-bonding input and output selection for memory resources.

FIG. 5 depicts a 3D-IC 500 in accordance with an embodiment in which passive memory elements 505 in a programmable interconnect layer 510 are used to vary the data width of a memory 515 in an underlying device layer 520.

FIG. 6 depicts a 3D-IC 600 in accordance with an embodiment that illustrates a further use of programmable interconnect layer 605 to selectively disable defective or unneeded circuitry in an adjacent wafer or wafer stack 610.

FIG. 7 is a flowchart 700 describing a method for assembling and programming 3D-ICs in accordance with one embodiment.

### DETAILED DESCRIPTION

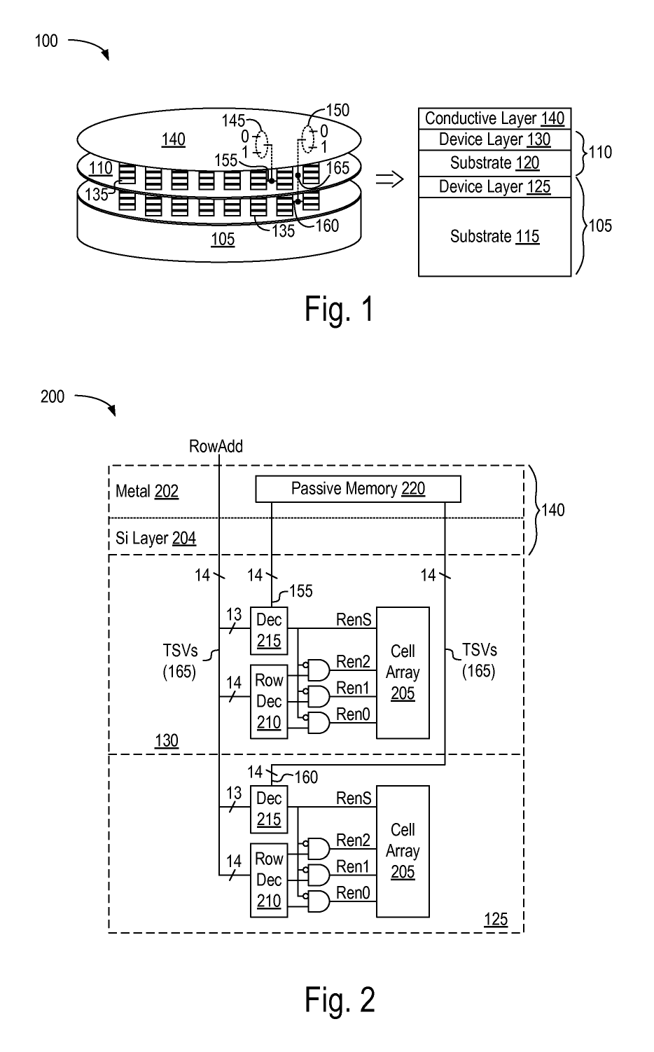

FIG. 1 depicts a three-dimensional integrated circuit (3D-IC) stack 100 that includes a stack of semiconductor wafers 105 and 110. As shown in the cut-away view at the right, each of wafers 105 and 110 includes a substrate 115/120 and a device layer 125/130. Programmable components 135, such as memory arrays or logic circuits, are formed within device layers 125 and 130. Some of components 135 are redundant, and can be substituted for defective components by programming a passive conductive layer 140. Layer 140 includes passive memory elements 145 and 150, such as fuses or antifuses, and is without active devices. Being devoid of active devices, layer 140 is relatively reliable and inexpensive. Layer 140 is e.g. a metallization layer on a semiconductor wafer (e.g., wafer 110) or a metallization layer disposed on an insulating passivation layer that overlays device layer 130 (of wafer 110). For purposes of the present disclosure, a device is “active” if it is capable of power gain. Active devices include, for example, latches, sense amplifiers, and some forms of memory cells. Passive elements, in contrast, are incapable of power gain. Common passive elements include fuses and antifuses.

Memory elements 145 and 150 connect to respective control ports 155 and 160, which are inputs to programmable components 135. Elements 145 and 150 can thus be used to selectively enable and disable programmable components 135 in device layers 125 and 130. Memory element 150 connects to control port 160 through wafer 110 by way of a through-silicon via (TSV) 165. Passive elements of an inexpensive repair layer can therefore be used to repair otherwise inaccessible sublayers. In some embodiments elements 145 and 150 are formed on a separate semiconductor layer. In such embodiments TSVs can connect elements 145 and 150 to the underlying device layer 130.

FIG. 2 is a block diagram 200 depicting aspects of an embodiment of 3D-IC stack 100 of FIG. 1, with like-identified elements being the same or similar. Substrates 115 and 120 are omitted from the stack in this illustration, and layer 140 is shown to include a metallization layer 202 disposed on a silicon substrate 204. Each of device layers 125 and 130 includes e.g. the following programmable components: a memory-cell array 205, a row-address decoder 210, a redundant-address decoder 215, and a number of AND gates. Each cell array 205 includes 2̂13 (about 8K) main rows of memory cells and one identical spare. The rows of cells are not shown, but are identified by three main row-enable lines Ren[2:0] and a spare line RenS. Other embodiments may have different numbers of main and spare rows.

External circuitry (not shown) can select from among the available rows of memory cells by asserting the appropriate 14-bit address on row address lines RowAdd, which are accessed via conductive layer 140 in this example. The most-significant bit (MSB) of the row address selects between device layers 125 and 130, while the remaining 13 bits select one of the main rows. Passive memory elements 220 in conductive layer 140 convey fourteen bits to each of decoders 215 via a respective one of control ports 155 and 160, and can be programmed to select the spare row should one of the main rows be found to be defective. Assuming, for example, that the row of memory cells associated with row-enable signal Ren2 of layer 130 is defective, memory 220 can be programmed to provide the defective row address to decoder 215 of the same layer. Responsive to the address for the defective row, that decoder 215 would then assert signal RenS to activate the spare row. The same signal RenS would likewise cause one of the AND gates to prevent activation of the defective row. Cell array 205 would thus activate the spare row in lieu of the defective one. Memory 220 can likewise be programmed to substitute out a bad row in device layer 125. Column redundancy can be supported on the different layers in a similar fashion, as will be readily apparent to those of skill in the art. Interior layers of the 3D-IC stack 100 can thus be repaired after the wafers are bonded.

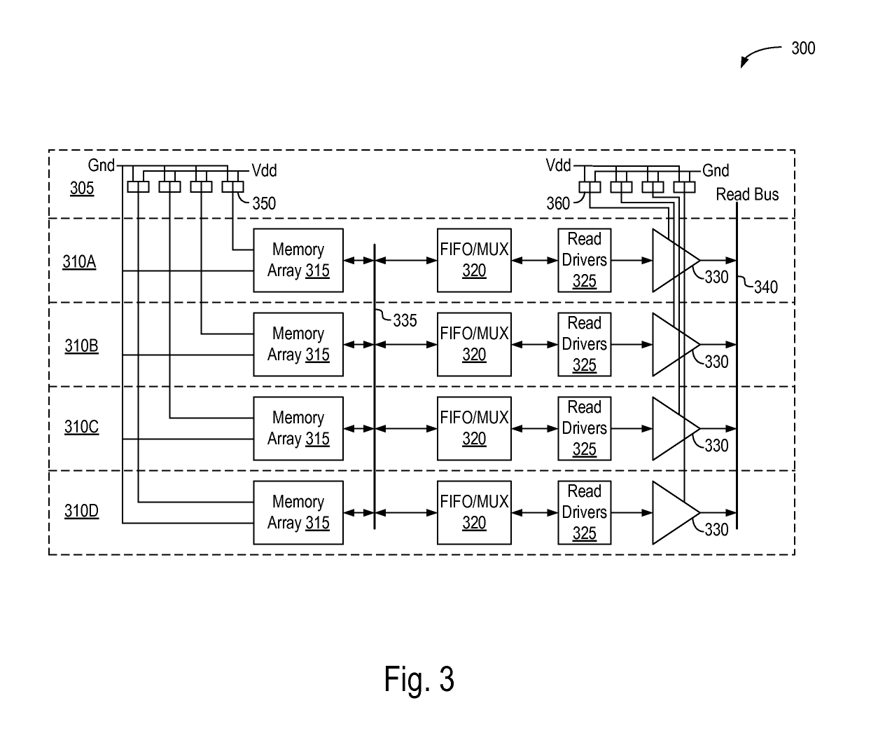

FIG. 3 depicts a 3D-IC 300 in accordance with an embodiment that supports different types of post-bonding repairs to memory and other circuit resources. 3D-IC 300 includes a conductive layer 305, once again devoid of active devices, overlying a number of identical wafers 310[A:D]. Each wafer 310 includes a memory array 315, first-in, first-out (FIFO) and multiplexing (MUX) circuitry 320, drivers 325, and a collection of output amplifiers 330. Other than the manner of programming, this circuitry is conventional. A detailed discussion is therefore omitted. The read/write ports of memory arrays 315 are interconnected by a bus 335 that employs through-silicon vias (TSVs) to create connections between layers. A read bus 340 likewise employs TSVs to connect the outputs from all four amplifiers 330 in parallel to circuits external to IC 300. Read bus 340 can be a bidirectional (read/write) bus in other embodiments, though write circuitry is omitted here for brevity.

Passive memory elements 350 in top layer 305 can be programmed to provide or deprive each array 315 of a supply voltage Vdd that is required for array operation. If the uppermost array 315 is defective, for example, the rightmost element 350 can be programmed to supply ground in lieu of Vdd, and thus disable the defective or unnecessary array. The remaining three memory arrays 315 can thus be addressed for write and read operations. In effect, these supply connections act as a control port that allows the 3D-IC to be programmed post bonding.

Memory arrays 315 connect in parallel to the same bus 335 and to all four of circuits 320. Only one set of the circuitry between buses 335 and 340 is required to communicate between buses 335 and 340. Passive memory element 360 in top layer 305 can therefore be programmed to disable one or more of amplifiers 330. Defective circuitry in one or more layers can therefore be effectively removed. Memory elements can control the application of supply voltages, as in the prior example, or can otherwise control the circuitry employed to access arrays 315.

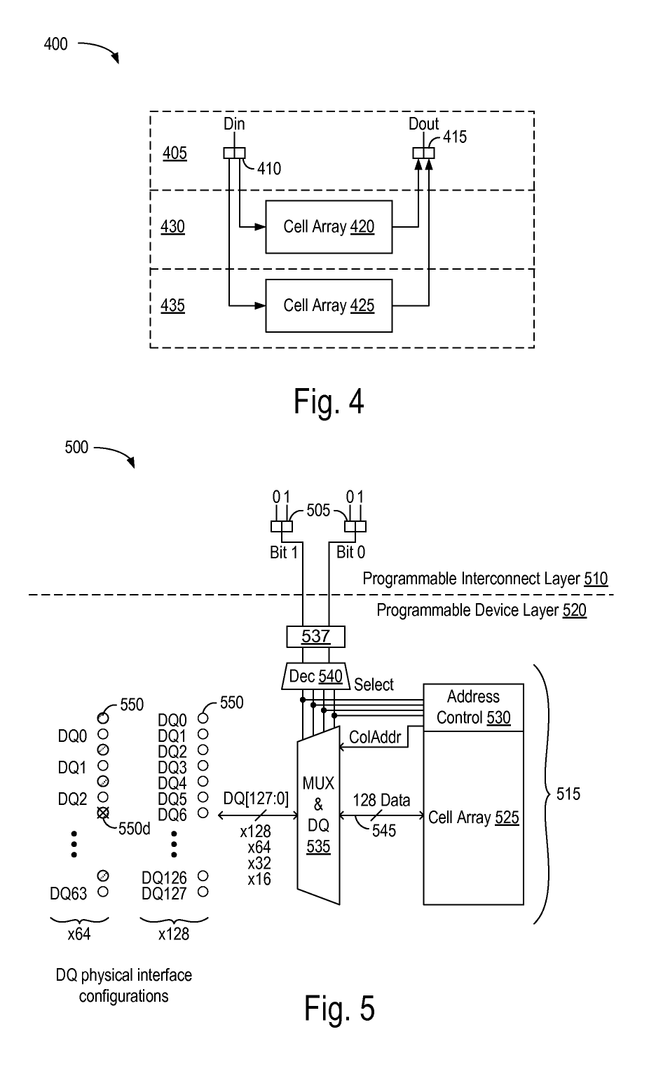

FIG. 4 depicts a 3D-IC 400 in accordance with an embodiment that supports post-bonding input and output selection for memory resources. 3D-IC 400 includes a conductive layer 405 with passive memory elements 410 and 415 to selectively control memory cell arrays 420 and 425. Though arrays 420 and 425 are included in separated wafers 430 and 435 in this example, arrays 420 and 425 can also be included in the same wafer. Memory element 410 serves as a demultiplexer that directs signals on an input node Din to a selected one of cell arrays 420 and 425. Memory element 415 serves as a multiplexer that directs the output of one of cell arrays 420 and 425 to an output node Dout. A defective cell array can therefore be disabled. The defective cell array can be deprived of a supply connection to save power, as detailed previously.

FIG. 5 depicts a 3D-IC 500 in accordance with an embodiment in which passive memory elements 505 in a programmable interconnect layer 510 are used to vary the data width of a memory 515 in an underlying device layer 520. Memory 515 includes a cell array 525 (e.g., a DRAM memory array), address control circuitry 530, multiplexer and DQ circuit 535, a fuse latch 537, and a data-width decoder 540. A 128-bit array data bus 545 provides bidirectional communication between array 525 and multiplexer and DQ circuit 535. The DQ circuitry (not shown) is coupled to the physical DQ interface. The DQ interface includes connections 550, depicted as circles, that define 128 inter-layer signal paths made up of circuit traces and TSVs. Configuration circuitry, such as a fuse latch 537, is optionally provided to capture and store the control-port values from programmable elements 505. Other than the repair aspect detailed herein, the operation of multiplexer and DQ circuit 535 is well understood by those of skill in the art. A detailed discussion is therefore omitted for brevity.

Memory elements 505 can be programmed to control decoder 540, and therefore multiplexer and DQ circuit 535, to pass 128-bit data between cell array 525 and the DQ physical interface. A 128-bit-wide configuration is depicted as the right DQ physical interface example at the lower left of FIG. 5. In essence, each connection 550 represents the connectivity required to communicate data to and from memory 515, and there are 128 such connections in this relatively wide configuration.

Elements 505 can be programmed to support narrower memory-device widths. A 64-bit configuration is depicted as the left DQ physical interface example at the lower left of FIG. 5. A connection 550d represents defective connectivity, such as an open TSV. Elements 505 are programmed such that multiplexer and DQ circuit 535 passes 64 of the 128 bits to and from cell array 525. Half of the connections 550, including defective connection 550d, are not required for this device width. The unused connections are highlighted with shading, and the remaining connections are labeled DQ[63:0] in this relatively narrow configuration.

Configuring memory 515 for narrower widths does not change memory capacity in some embodiments. Rather, narrower data widths provide larger address ranges. A width configuration of 64 bits will have double the address range as a width configuration of 128 bits, for example. Select bits from decoder 540 can be provided to address control circuitry 530 to change the addressing scheme with device width. One or more column address bits can be conveyed from address control circuitry 530 to multiplexer and DQ circuit 535 to distinguish between subsets of the 128 bits from cell array 525. In the half-width (64-bit) configuration, for example, multiplexer and DQ circuit 535 can couple 64 bits of the physical interface to either the 64 low-order bits or the 64 high-order bits of the 128 connections to cell array 525 based on the state of one column-address bit.

The two bits of storage offered by programming elements 505 can express up to four width configurations (e.g., x128, x64, x32, and x16). This flexibility may be used to address defects, as detailed previously, or can be used to tailor device width for a given application. For example, different processing cores (e.g. CPU, Video, or GPU cores) may have different optimum data-path widths. In the alternative, the two bits can express fewer but different width configurations. In one embodiment, for example, different programming options can be used to select different subsets of connections 550 to provide more flexibility in avoiding defective resources. In still other embodiments more and different programming options can support more flexibility, additional width configurations, or both.

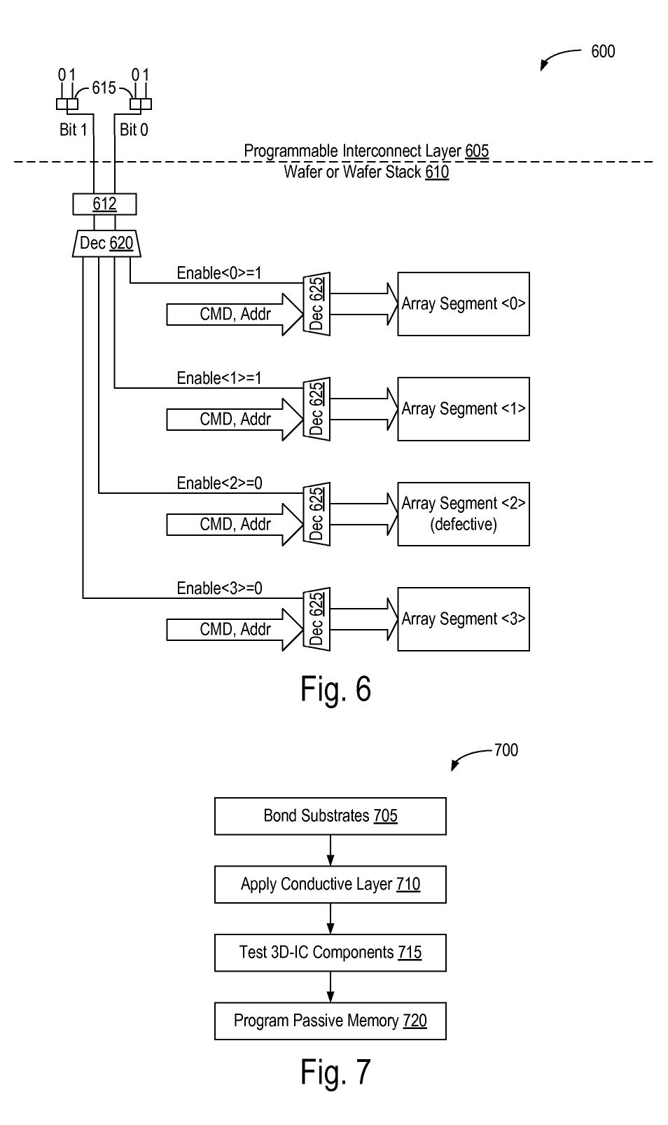

FIG. 6 depicts a 3D-IC 600 in accordance with an embodiment that illustrates a further use of programmable interconnect layer 605 to selectively disable defective or unneeded circuitry in an adjacent wafer or wafer stack 610. In this example, one of four array segments, segment <2>, is defective. A latch 612 captures the state of a pair of passive memory elements 615 that are programmed to cause a decoder 620 to assert signals Enable <0:1> and de-assert signals Enable <2:3>. Four command and address decoders 625, responsive to the outputs from decoder 620, disable commands and addresses to the upper half of the address space (array segments <2:3>), avoiding defective array segment <2>. 3D-IC 600 therefore provides fully functional memory, albeit with reduced capacity, despite the presence of defective memory resources. The arrays segments can be integrated in the same wafer, in which case the input to decoder 620 acts as the control port; alternatively, the array segments can be spread between bonded wafers, each wafer having its own control port.

FIG. 7 is a flowchart 700 describing a method for assembling and programming 3D-ICs in accordance with one embodiment. This process assumes the existence of substrates upon and within which are instantiated programmable, active components, such as memory arrays and digital logic circuitry. These substrates are aligned and bonded (705). Vertical connections, or TSVs, are either built into the wafers before bonding or else created in the stack after bonding. Methods for fabricating and bonding substrates are well known to those of skill in the art. In any case, TSVs provide electrical contact through and between substrates as detailed above. A conductive layer devoid of active devices is bonded to the other substrates (710), which can be done as a separate boding process or simultaneous with the other substrates.

In other embodiments the 3D-IC is formed using a monolithic manufacturing process in which multiple device layers are grown on the same wafer in a serial manner. For example, once a layer of devices and their associated interconnect are completed on a substrate, an interlevel dielectric layer of e.g. silicon dioxide can be deposited. A successive layer of devices and interconnect can then be grown over the interlevel dielectric. Vias can be formed through the dielectric layers.

However the device layers are vertically integrated, the resultant stack is subjected to test procedures that identify defective components or interconnections (715). The conductive layer can include test ports to provide the requisite access points. Finally, passive memory elements in the conductive layer are programmed to disregard defective components within the stack (720). Such programming can disable or disconnect defective resources from supply terminals or other components, or can selectively enable or connect known-good resources. Suitable passive programming technologies can be based on e.g. metallization options, laser fuses, e-fuses, antifuses, customizable masks, or e-beam customization of metal layers. In the case of metallization options, a mask option or e-beam customization, the passive memory elements can be the presence or absence of a conductor.

In the foregoing description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Moreover, the foregoing descriptions focus primarily on read access, but these embodiments likewise support write access, as will be well understood by those of skill in the art.

While the present invention has been described in connection with specific embodiments, after reading this disclosure variations of these embodiments will be apparent to those of ordinary skill in the art. For example, programming options described in connection with different figures can be combined in a single IC. Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. §112.

What is claimed is:

1. A three-dimensional integrated circuit (3D-IC) comprising:
a first semiconductor substrate having a first device layer, the first device layer including first programmable components and a first control port coupled to the first programmable components, the first control port to selectively enable the first programmable components;
a second semiconductor substrate disposed on and bonded to the first semiconductor substrate, the second semiconductor substrate having a second device layer that includes second programmable components and a second control port coupled to the second programmable components, the second control port to selectively enable the second programmable components, the second semiconductor substrate including conductive vias extending from the first control port through the second semiconductor substrate; and
a conductive layer devoid of active devices and including first passive memory elements coupled to the first control port by the conductive vias and second passive memory elements coupled to the second control port.

2. The 3D-IC of claim 1, wherein the conductive layer is disposed on a third substrate bonded to the second semiconductor substrate.

3. The 3D-IC of claim 2, wherein the second substrate is of a semiconductor.

4. The 3D-IC of claim 2, wherein the conductive layer is in contact with the third substrate.

5. The 3D-IC of claim 1, wherein the first and second semiconductor substrates include configuration circuitry, and wherein the first and second control ports extend to the configuration circuitry.

6. The 3D-IC of claim 1, wherein the first device layer includes a power-supply node and the second semiconductor substrate includes a supply via extending through the second semiconductor substrate to the conductive layer.

7. The 3D-IC of claim 1, wherein the first programmable components include an individually powered memory bank having a supply node connected to the conductive layer by a corresponding one of the vias.

8. The 3D-IC of claim 1, wherein the programmable components include spare memory arrays, and wherein fuse latches assign addresses to the memory arrays based on program states of the passive elements.

9. The 3D-IC of claim 1, the first substrate including memory test ports and the second substrate including second vias extending from the test ports to the conductive layer.

10. The 3D-IC of claim 1, wherein the passive memory elements are electrically programmable.

11. The 3D-IC of claim 10, wherein the passive memory elements include at least one of fuses or antifuses.

12. The 3D-IC of claim 1, further comprising configuration circuitry, wherein the first and second control ports are coupled to the respective first and second programmable components via the configuration circuitry.

13. The 3D-IC of claim 1, wherein the first and second programmable components include a memory array.

14. The 3D-IC of claim 1, wherein the passive memory element comprise alternative present or absent conductors.

15. A method of fabricating an integrated circuit, the method comprising:
bonding a semiconductor substrates, each substrate having a device layer including programmable components and a control port coupled to the programmable components to selectively enable the programmable components;
bonding a conductive layer to the semiconductor substrates, the conductive layer devoid of active devices and including passive memory elements coupled to the control ports by conductive vias that extend through at least one of the substrates;
testing the programmable components to identify defective ones of the programmable components; and
programming the passive memory elements to disregard the defective ones of the programmable components.

16. The method of claim 15, wherein the bonding of the semiconductor substrates and the conductive layer occur simultaneously.

17. The method of claim 15, wherein the programmable components include arrays of memory cells.

18. The method of claim 15, wherein the passive memory elements include at least one of fuses and antifuses.

19. The method of claim 15, wherein the conductive layer overlays a second substrate.

20. The method of claim 19, wherein the second substrate is a semiconductor substrate.

21. The method of claim 15, wherein programming the passive memory elements includes customizing a metal layer using at least one of metallization options, laser fuses, customizable masks, and e-beam customization of the metal layer.

22. An integrated circuit (IC) comprising:
stacked semiconductor substrates, each substrate supporting programmable components and including conductive vias; and
a conductive layer overlaying the stacked semiconductor substrates and devoid of active devices, the conductive layer including passive memory elements coupled to the programmable components by the conductive vias.

23. The IC of claim 22, wherein the passive memory elements store state information, and wherein the state information selectively disables a subset of the programmable components.

24. The IC of claim 22, wherein the conductive layer is disposed on a layer of insulator or semiconductor bonded to the stacked substrates.
